(19) United States
(12) Patent Application Publication
(10) Pub. No.: US 2026/0040549 A1
(43) Pub. Date: Feb. 5, 2026

(54) MICROELECTRONIC DEVICES, AND RELATED METHODS AND MEMORY DEVICES

(71) Applicant: Micron Technology, Inc., Boise, ID (US)

(72) Inventors: Ramanathan Gandhi, Singapore (SG); Lakshmi Suresh, Singapore (SG); Arvind Soundarapandian, Singapore (SG)

(21) Appl. No.: 19/254,462

(22) Filed: Jun. 30, 2025

Related U.S. Application Data
(60) Provisional application No. 63/677,227, filed on Jul. 30, 2024.

(51) Int. Cl. H10B 43/27

(52) U.S. Cl. CPC H10B 43/27

(57) ABSTRACT

A microelectronic device includes a stack structure, a pillar structure, and an interfacial liner material. The stack structure includes levels of conductive material vertically alternating with levels of insulative material. The pillar structure includes semiconductor material vertically extending through the stack structure. The interfacial liner material is horizontally interposed between the pillar structure and the levels of the conductive material of the stack structure. The interfacial liner material has a work function within a range of from about 4.6 eV to 6.0 eV. Methods of forming a microelectronic device, memory devices, and electronic systems are also described.

### CROSS-REFERENCE TO RELATED APPLICATION

This application claims the benefit under 35 U.S.C. § 119(e) of U.S. Provisional Patent Application Ser. No. 63/677,227, filed Jul. 30, 2024, the disclosure of which is hereby incorporated herein in its entirety by this reference.

### TECHNICAL FIELD

The disclosure, in various embodiments, relates generally to microelectronic device design and fabrication. More particularly, the disclosure relates to design and fabrication of microelectronic devices including high work function materials.

### BACKGROUND

Semiconductor memory devices may be classified into volatile memory devices and nonvolatile memory devices. In contrast to volatile memory devices, nonvolatile memory devices, such as flash memory devices, retain stored data even when power is removed. Therefore, nonvolatile memory devices, such as flash memory devices, are widely used in memory cards and in electronic devices. A three-dimensional (3D)-NAND flash memory device is a type of non-volatile flash memory device in which the memory cells are stacked vertically to increase storage density.

Due to rapidly growing digital information technology, there are demands to continuingly increase the memory density of the flash memory devices while maintaining, if not reducing, the size of the devices. Although it is desirable to stack more and more vertical layers on top of each other in a three-dimensional arrangement to further increase the memory density, such an approach presents several challenges to the functionality and reliability of the memory cells.

### BRIEF DESCRIPTION OF THE DRAWINGS

FIGS. 1A through 1E are simplified, vertical cross-sectional views of various processing stages in a method of forming microelectronic device structure for a microelectronic device, according to some embodiments of the disclosure;

FIGS. 2A and 2B are simplified, vertical cross-sectional views of various processing stages in a method of forming a microelectronic device structure for a microelectronic device, according to some other embodiments of the disclosure;

FIGS. 3A through 3E are simplified, vertical cross-sectional views of various processing stages in a method of forming a microelectronic device structure for a microelectronic device, according to some further embodiments of the disclosure;

FIG. 4 is a simplified, horizontal cross-sectional view of a portion of the microelectronic device structure shown in FIG. 1E, taken through line A-A in FIG. 1E, according to some embodiments of the disclosure;

FIG. 5 is a simplified, horizontal cross-sectional view of a portion of the microelectronic device structure shown in FIG. 1E, taken through line A-A in FIG. 1E, according to some additional embodiments of the disclosure;

FIG. 6 is a simplified, horizontal cross-sectional view of a portion of the microelectronic device structure shown in FIG. 1E, taken through line A-A in FIG. IE, according to some other embodiments of the disclosure; and

FIG. 7 is a schematic block diagram illustrating an electronic system, in accordance with embodiments of the disclosure.

### DETAILED DESCRIPTION

The following description provides specific details, such as material types. material thicknesses, and processing conditions in order to provide a thorough description of embodiments of the disclosure. However, a person of ordinary skill in the art will understand that embodiments of the present disclosure may be practiced without employing these specific details. Indeed, the embodiments of the present disclosure may be practiced in conjunction with conventional fabrication techniques employed in the industry. In addition, the description provided herein does not form a complete process flow for forming a semiconductor device structure, and the semiconductor device structures described below do not form a complete semiconductor device. Only those process acts and structures necessary to understand the embodiments of the present disclosure are described in detail below. Additional acts to form the complete semiconductor device may be performed by conventional fabrication techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. Furthermore, the drawings accompanying the application are for illustrative purposes only, and are thus not necessarily drawn to scale. Elements common between figures may retain the same numerical designation. While the materials described and illustrated herein may be formed as layers, the materials are not limited thereto and may be formed in other three-dimensional configurations.

As used herein, the singular forms following “a,” “an,” and “the” are intended to include the plural forms as well, unless the context clearly indicates otherwise.

As used herein, “and/or” includes any and all combinations of one or more of the associated listed items.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, the term “about” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “memory device” means and includes microelectronic devices exhibiting memory functionality, but not necessarily limited to memory functionality. Stated another way, and by way of example only, the term “memory device” means and includes not only memory (e.g., volatile memory, such as dynamic random access memory (DRAM); non-volatile memory, such as NAND memory), but also includes an application specific integrated circuit (ASIC) (e.g., a system on a chip (SoC)), an electronic device combining logic and memory, or a graphics processing unit (GPU) incorporating memory.

As used herein, the term “electronic device” includes, without limitation, a memory device, as well as a semiconductor device which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, the term “work-function” refers to a bulk chemical potential of a material (e.g., metal) relative to the vacuum level.

As used herein, the term “substrate” means and includes a base material or construction upon which additional materials are formed. The substrate may be, for example, a semiconductor substrate, a base semiconductor material on a supporting structure, a metal electrode or a semiconductor substrate having one or more materials, structures or regions formed thereon. The substrate may be a conventional silicon substrate, or other bulk substrate comprising a layer of semiconductive material. As used herein, the term “bulk substrate” means and includes not only silicon wafers, but also silicon-on-insulator (SOI) substrates, such as silicon-on-sapphire (SOS) substrates and silicon-on-glass (SOG) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. The substrate may be doped or undoped. By way of non-limiting example, a substrate may comprise at least one of silicon, silicon dioxide, silicon with native oxide, silicon nitride, a carbon-containing silicon nitride, glass, semiconductor, metal oxide, metal, titanium nitride, carbon-containing titanium nitride, tantalum, tantalum nitride, carbon-containing tantalum nitride, niobium, niobium nitride, carbon-containing niobium nitride, molybdenum, molybdenum nitride, carbon-containing molybdenum nitride, tungsten, tungsten nitride, carbon-containing tungsten nitride, copper, cobalt, nickel, iron, aluminum, and a noble metal.

As used herein, the term “conductive material” means and includes an electrically conductive material, such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, a “insulative material” or a “dielectric material” means and includes an electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). As used herein, an “insulative structure” means and includes a structure formed of and including one or more insulative materials. As used herein, a “dielectric structure” means and includes a structure formed of and including one or more dielectric materials.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., AlₓGa₁₋ₓAs), and quaternary compound semiconductor materials (e.g., GaₓIn₁₋ₓAs_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn₂O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn₂O), gallium zinc tin oxide (GaₓZn_{y}Sn_{z}O), zirconium zinc tin oxide (ZrₓZn_{y}Sn_{z}O), and other similar materials. In addition, each of a “microelectronic device structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC₂N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “selectively removable” means and includes a material that exhibits a greater removal rate responsive to exposure to a given removing (e.g., etching) chemistry and/or process conditions relative to another material exposed to the same removal chemistry and/or process conditions. For example, the material may exhibit a removal rate that is at least about five times greater than the removal rate of another material, such as a removal rate of about ten times greater, about twenty times greater, or about forty times greater than the removal rate of the another material. Removal chemistries and conditions (e.g., etch chemistries and etch conditions) for selectively removing a desired material may be selected by a person of ordinary skill in the art.

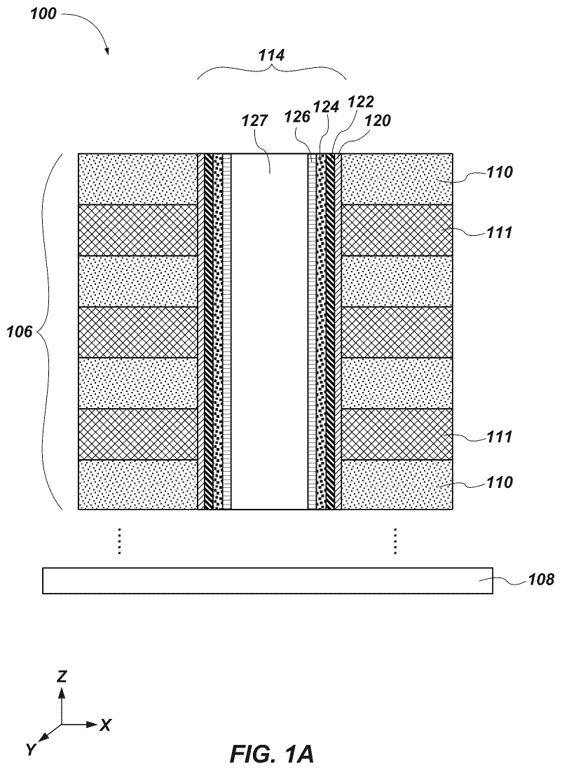

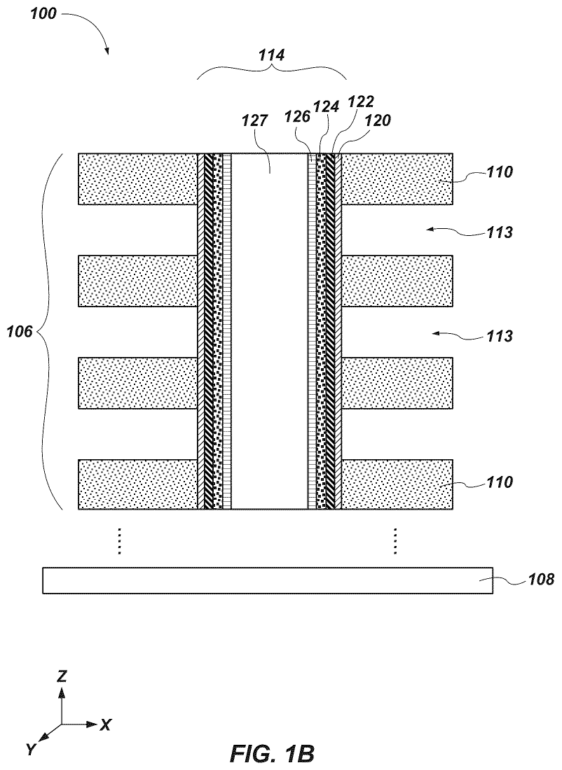

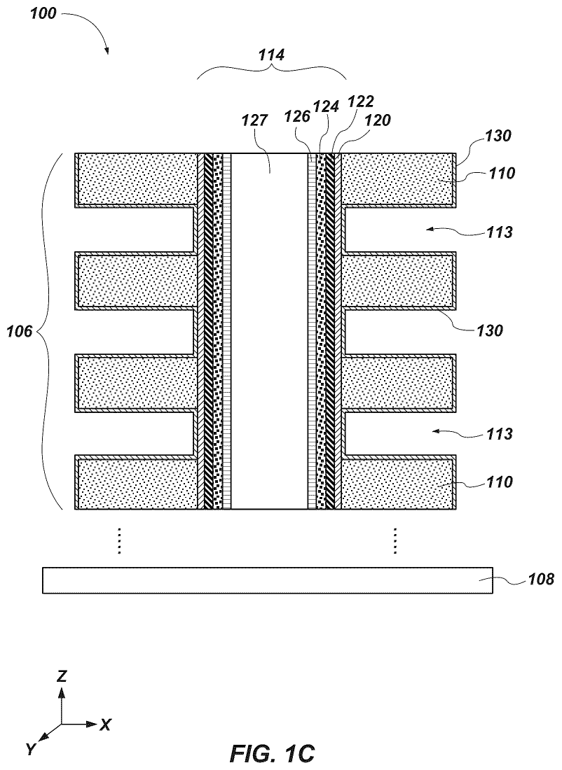

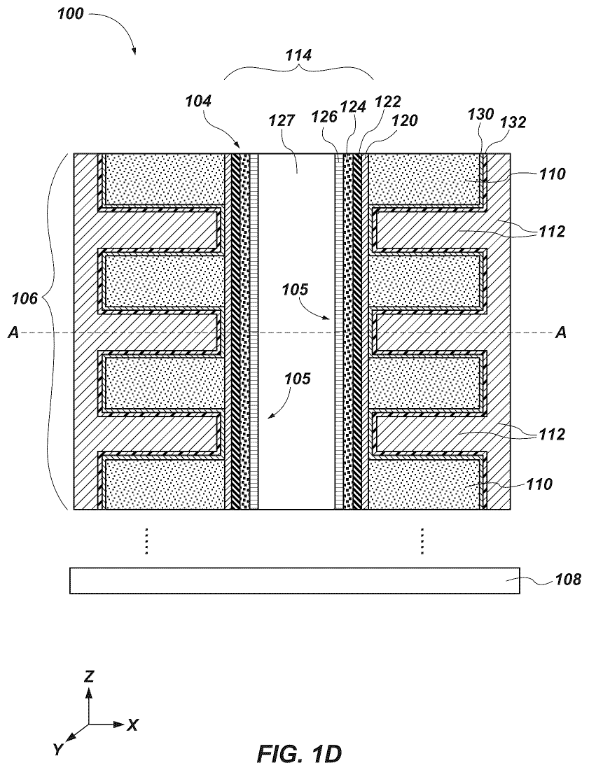

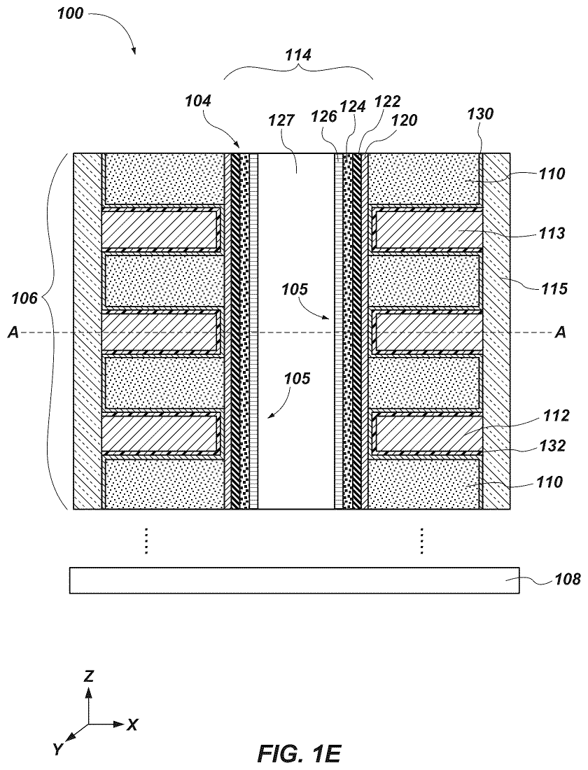

FIGS. 1A through 1E are simplified, vertical cross-sectional views of various processing stages of a method of forming a microelectronic device structure (e.g., a memory device structure) for a microelectronic device (e.g., a memory device, such as a 3D NAND Flash memory device), according to some embodiments of the present disclosure. As described in further detail below, the method described with reference to FIGS. 1A through IE may effectuate the formation of a microelectronic device including vertically extending strings of memory cells. wherein the microelectronic device has enhanced performance characteristics relative to conventional microelectronic devices including vertically extending strings of memory cells.

Referring to FIG. 1A, a microelectronic device structure 100 may be formed to include a stack structure 106 having vertically alternating sequence of insulative material 110 and sacrificial material 111 (e.g., additional insulative material) on or over a substrate 108; and at least one pillar structure 114 (e.g., cell pillar structure) vertically extending through the stack structure 106. The substrate 108 may, for example, include at least one source structure in electrical communication with the pillar structure 114. Although the pillar structure 114 shown in FIG. 1A has a generally cylindrical shape vertically extending through the stack structure 106, the disclosure is not limited and the pillar structure 114 may have a geometric configuration such as, without limitation, a frustoconical shape.

Each level (e.g., vertical elevation) of the insulative material 110 and the sacrificial material 111 may respectively have a desired vertical thickness. Each level of the insulative material 110 may have substantially the same vertical thickness as one another, or at least one level of the insulative material 110 may have a different vertical thickness than at least one other level of the insulative material 110. Furthermore, each level of the sacrificial material 111 may have substantially the same vertical thickness as one another, or at least one level of the sacrificial material 111 may have a different thickness than at least one other level of the sacrificial material 111. In some embodiments, the insulative material 110 and the sacrificial material 111 respectively have a vertical thickness within a range of from about 10 nanometers (nm) to about 400 nm. In some embodiments, the insulative material 110 and the sacrificial material 111 respectively have a vertical thickness within a range of from about 10 nm to about 50 nm, such as from about 20 nm to about 50 nm.

In FIG. 1A, the stack structure 106 is shown as having four levels of insulative material 110 and three level of sacrificial material 111. However, the disclosure is not limited; and fewer or more levels of the insulative material 110 and/or the sacrificial material 111 may be included in the stack structure 106. A quantity of vertically alternating levels of the insulative material 110 and sacrificial material 111 may, for example, be within a range from about two (2) to about one-thousand and twenty-four (1024). In addition, the levels of the insulative material 110 and the levels of the sacrificial material 111 may be arranged in tiers within the stack structure 106, wherein each tier includes one of the levels of the insulative material 110 vertically neighboring one of the levels of the sacrificial material 111.

The insulative material 110 of the stack structure 106 may be formed of and include at least one insulative material having different etch selectivity than the sacrificial material 111 of the stack structure 106. In some embodiments, the insulative material 110 is formed of and includes SiOₓ (e.g., SiO₂). The sacrificial material 111 of the stack structure 106 may be formed of include at least one material that can be removed selectively relative to the insulative material 110. As a non-limiting example, the sacrificial material 111 may be removed at etch rate that is at least times (2×) faster than an etch rate of the insulative material 110 during mutual expose to an etchant (e.g., a wet etchant). The sacrificial material 111 may, for example, be formed of and include one or more of insulative material, semiconductor material, and conductive material. In some embodiments, the sacrificial material 111 is formed of and includes SiN_{y} (e.g., Si₃N₄).

As shown in FIG. 1A, the pillar structure 114 may be formed to include a stack of materials that collectively facilitate the formation of a vertically extending string of memory cells following subsequent processing of the microelectronic device structure, as described in further detail below. For example, the pillar structure 114 may be formed to include a charge-blocking material 120, such as first dielectric oxide material (e.g., SiOₓ, such as SiO₂; AlOₓ, such as Al₂O₃); a charge-trapping material 122, such as a dielectric nitride material (e.g., SiN_{y}, such as Si₃N₄); a tunnel dielectric material 124, such as a second oxide dielectric material (e.g., SiOₓ, such as SiO₂); a channel material 126, such as a semiconductor material (e.g., silicon, such as polycrystalline Si); and a fill material 127, such as a dielectric fill material (e.g., dielectric oxide, dielectric nitride, air). The charge-blocking material 120 may be formed on or over, and may substantially cover, surfaces of the microelectronic device structure 100 defining boundaries (e.g., horizontal boundaries, lower vertical boundaries) of the pillar structures 114, such as surfaces of the levels of insulative material 110 and the sacrificial material 111 of the stack structure 106. The charge-trapping material 122 may be formed on or over inner surfaces of the charge-blocking material 120. The tunnel dielectric material 124 may be formed on or over inner surfaces of the charge-trapping material 122. The channel material 126 may be formed on or over inner surfaces of the tunnel dielectric material 124. The dielectric fill material 127 may be formed on or over inner surfaces of the channel material 126.

Referring next to FIG. 1B, the microelectronic device structure 100 of FIG. JA is subjected to material removal process (e.g., a stripping process, such as a wet nitride stripping (WNS) process) to selectively remove the levels of the sacrificial material 111 (FIG. 1A) relative to the levels of insulative material 110. As a non-limiting example, when the insulative material 110 includes SiO₂ and the sacrificial material 111 (FIG. 1A) includes Si₃N₄, the sacrificial material 111 may be selectively removed using phosphoric acid as an etchant. As shown in FIG. 1B, the removal of the levels of sacrificial material 111 (FIG. 1A) may effectuate the formation of voids 113 vertically alternating with the levels of insulative material 110. The voids 113 may respectively be at least partially defined by exposed surfaces of the insulative material 110 (e.g., of two levels of the insulative material 110) and the pillar structure 114 (e.g., of the charge-blocking material 120 thereof).

Referring next to FIG. 1C, a high-K dielectric material 130 may be formed (e.g., substantially continuous formed) on exposed surfaces defining boundaries of the voids 113, such as on exposed surfaces of the insulative material 110 and charge-blocking material 120 of the pillar structure 114. The high-K dielectric material 130 may substantially continuously line and partially fill the voids 113. In addition, the high-K dielectric material 130 may be formed on or over exposed surfaces of the microelectronic device structure 100 outside of boundaries of the voids 113, such as on or over additional exposed surfaces within the levels of insulative material 110. As used herein, the term “high-K dielectric material” refers to a material with a higher dielectric constant than SiO₂. Any known high-K dielectric materials may be used for the high-K dielectric material 130. By way of non-limiting example, the high-K dielectric material 130 may be formed of and include one or more of hafnium oxide, zirconium oxide, vanadium oxide, titanium oxide, tin oxide, aluminum oxide, zinc oxide, hafnium silicon oxide, and zirconium silicon oxide. In some embodiments, the high-K dielectric material 130 may have a thickness within a range of from about 1 nanometer (nm) to about 5 nm.

Referring next to FIG. 1D, interfacial liner material 132 may be formed (e.g., substantially continuously formed) on or over the high-K dielectric material 130, and then a conductive fill material 112 may be formed over the high-K dielectric material 130. As shown in FIG. 1D, the interfacial liner material 132 may be formed to substantially extend (e.g., horizontally extend and vertically extend) over and cover portions of the high-K dielectric material 130 within the voids 113 (FIG. 1C). The interfacial liner material 132 may partially (e.g., less than completely) fill remaining portions of the voids 113 (FIG. 1C) unoccupied by the high-K dielectric material 130. In addition, the interfacial liner material 132 may continuously extend over portions of the high-K dielectric material 130 outside of the voids 113 (FIG. 1C) as well. Following the formation of the interfacial liner material 132, the conductive fill material 112 may be formed to substantially fill yet still remaining portions of the voids 113 (FIG. 1C) unoccupied by the high-K dielectric material 130 and the interfacial liner material 132. The conductive fill material 112 may also extend over portions of the interfacial liner material 132 outside of the voids 113 (FIG. 1C) as well. Following subsequent processing, portions of the conductive fill material 112 outside of the boundaries of the voids 113 (FIG. 1C) may be removed to form conductive structures (e.g., local word line structures, select gate structures) for the microelectronic device structure, as described in further detail below with reference to FIG. 1E.

In some embodiments, the interfacial liner material 132 is formed of and includes a molybdenum-containing material, such as one or more of molybdenum oxide. molybdenum nitride, and molybdenum oxynitride. Molybdenum oxide, molybdenum nitride, and molybdenum oxynitride, as any or all of these materials may be employed within the interfacial liner material 132, are described in further detail below.

As used herein, the term “molybdenum oxide” means and includes a material including molybdenum atoms and oxygen atoms. Molybdenum oxide may be a stoichiometric compound or a non-stoichiometric compound. As a non-limiting example, a percentage of oxygen content relative to oxygen saturation in the molybdenum oxide may be from about 0.5% to about 100%, wherein 100% oxide content means that the molybdenum oxide includes a saturated level of oxygen. In some embodiments. the percentage oxygen content relative to oxygen saturation for molybdenum oxide of the interfacial liner material 132 is at least about 20%. Within the interfacial liner material 132, molybdenum oxide may be substantially homogeneous in composition, with the oxygen atoms distributed substantially uniformly therein. Alternatively, within the interfacial liner material 132, the molybdenum oxide may be heterogeneous in composition (e.g., have a gradient change in the composition, have a step-wise change in the composition) with a higher concentration of oxygen atoms in one region thereof relative to at least one other region thereof. In some embodiments, portions of molybdenum oxide of the interfacial liner material 132 to be relatively more proximate to the conductive fill material 112 have a relatively greater oxygen content than additional portions of molybdenum oxide material to be relatively more distal from conductive fill material 112. In other embodiments, portions of molybdenum oxide of the interfacial liner material 132 to be relatively more proximate to the conductive fill material 112 have a lower oxygen content than the portions of molybdenum oxide relatively more distal from the conductive fill material 112.

As used herein, the term “molybdenum nitride” means and includes a material including molybdenum atoms and nitrogen atoms. Molybdenum nitride may be a stoichiometric compound or a non-stoichiometric compound. As a non-limiting example, a percentage of nitrogen content relative to nitrogen saturation in the molybdenum nitride may be from about 0.5% to about 100%, wherein 100% nitrogen content means that the molybdenum nitride includes a saturated level of nitrogen. In some embodiments, the percentage nitrogen content relative to nitrogen saturation for molybdenum nitride of the interfacial liner material 132 is at least about 20%. Within the interfacial liner material 132, molybdenum nitride may be substantially homogeneous in composition, with nitrogen atoms distributed substantially uniformly therein. Alternatively, within the interfacial liner material 132, the molybdenum nitride may be heterogeneous in composition (e.g., have a gradient change in the composition, have a step-wise change in the composition) with a greater concentration of nitrogen atoms in one region thereof relative to at least one other region thereof. In some embodiments, the portions of molybdenum nitride of the interfacial liner material 132 to be relatively more proximate to the conductive fill material 112 have a relatively greater nitrogen content than additional portions of molybdenum nitride material to be relatively more distal from the conductive fill material 112. In other embodiments, portions of molybdenum nitride of the interfacial liner material 132 to be relatively more proximate to the conductive fill material 112 have a relatively lower nitrogen content than additional portions of molybdenum nitride to be relatively more distal from the conductive fill material 112.

As used herein, the term “molybdenum oxynitride” means and includes a material including molybdenum atoms, oxygen atoms, and nitrogen atoms. Molybdenum oxynitride may be a stoichiometric compound or a non-stoichiometric compound. As a non-limiting example, a percentage of combined oxygen and nitrogen content relative to combined oxygen and nitrogen saturation in the molybdenum oxynitride may be from about 0.5% to about 100%, wherein 100% combined oxygen and nitrogen content means that the molybdenum oxynitride includes a saturated level of both oxygen and nitrogen. In some embodiments, the percentage combined oxygen and nitrogen content relative to oxygen and nitrogen saturation for molybdenum oxynitride of the interfacial liner material 132 is at least about 20%. Within the interfacial liner material 132, molybdenum oxynitride may be substantially homogeneous in composition, with oxygen atoms and nitrogen atoms distributed substantially uniformly therein. Alternatively, within the interfacial liner material 132, the molybdenum oxynitride may be heterogeneous in composition (e.g., have a gradient change in the composition, have a step-wise change in the composition) with a greater concentration of one or more of oxygen atoms and nitrogen atoms in one region thereof relative to at least one other region thereof. In some embodiments, the portions of molybdenum oxynitride of the interfacial liner material 132 to be relatively more proximate to the conductive fill material 112 have a relatively greater content of oxygen and/or nitrogen than additional portions of molybdenum nitride material to be relatively more distal from the conductive fill material 112. In other embodiments, portions of molybdenum nitride of the interfacial liner material 132 to be relatively more proximate to the conductive fill material 112 have a relatively lower content of oxygen and/or nitrogen than additional portions of molybdenum nitride to be relatively more distal from the conductive fill material 112.

The interfacial liner material 132 may be a high work function material having a work function of greater than or equal to 4.6 eV. As a non-limiting example, the interfacial liner material 132 may have a work function within a range of from about 4.6 eV to about 6.0 eV. In embodiments wherein the interfacial liner material 132 is formed of and includes one or more of molybdenum oxide, a molybdenum nitride, and a molybdenum oxynitride, the work function of the interfacial liner material 132 may depend on the amount of nitrogen and/or oxygen in the interfacial liner material 132.

With continued reference to FIG. 1D. the conductive fill material 112 may be formed of and include conductive material having a relatively lower work function than that of the interfacial liner material 132. In some embodiments, the control gate structure has a work function of from about 3.5 eV to about 4.6 eV. The conductive fill material 112 may include one or more of at least one elemental metal (e.g., molybdenum, tungsten, titanium, cobalt, nickel, platinum, ruthenium, copper); at least one conductive metal-containing material (e.g., metal nitride, metal silicide, metal carbide); and at least one conductively-doped-semiconductor material (e.g., silicon, gallium), so long as the work function of the conductive fill material 112 is relatively lower than the work function of the interfacial liner material 132. For example, conductive fill material 112 may be formed of and include one or more of copper (Cu), cobalt (Co), tungsten (W), aluminum (Al), ruthenium (Ru), iridium (Ir), molybdenum (Mo), platinum (Pt), tantalum (Ta), titanium (Ti), and rhodium (Rh). In some embodiments, the conductive fill material 112 is formed of and includes molybdenum (Mo). In some embodiments, the conductive fill material 112 is substantially free of silicon. In some embodiments, the conductive fill material 112 is formed a single (e.g., only one) material (e.g., only one elemental metal, only one single metal-containing material) having a work function within a range of from about 3.5 eV to about 4.6 eV. In some other embodiments, the conductive fill material 112 comprises multiple materials (e.g., multiple elemental metals, multiple metal-containing materials) that in combination have a work function within a range of from about 3.5 eV to about 4.6 eV.

Referring to FIG. 1E, following the formation of the conductive fill material 112, portions of the conductive fill material 112 outside of the boundaries of the voids 113 (FIG. 1C) may be removed (e.g., etched) to form discrete levels of the interfacial liner material 132 and the conductive fill material 112, and then the resulting slots may be filled with dielectric material (e.g., SiOₓ) to form dielectric slot structures 115. The discrete levels of the interfacial liner material 132 and the conductive fill material 112 may form conductive structures 113 of the microelectronic device structure 100. In turn, intersections of the pillar structures 104 and some of the conductive structures 113, together with portions of the high-K dielectric material 130 therebetween, may form vertically extending strings 104 of memory cells 105 for the microelectronic device structure 100 (and, hence, a microelectronic device formed to include the microelectronic device structure 100).

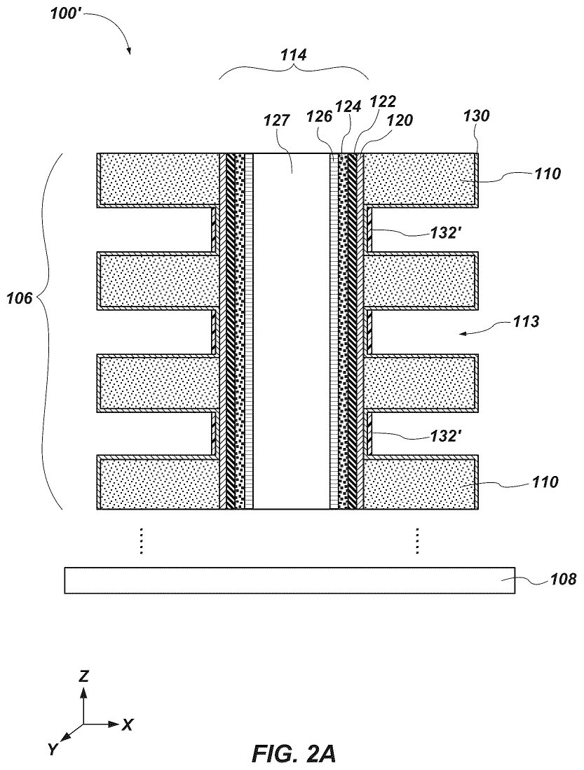

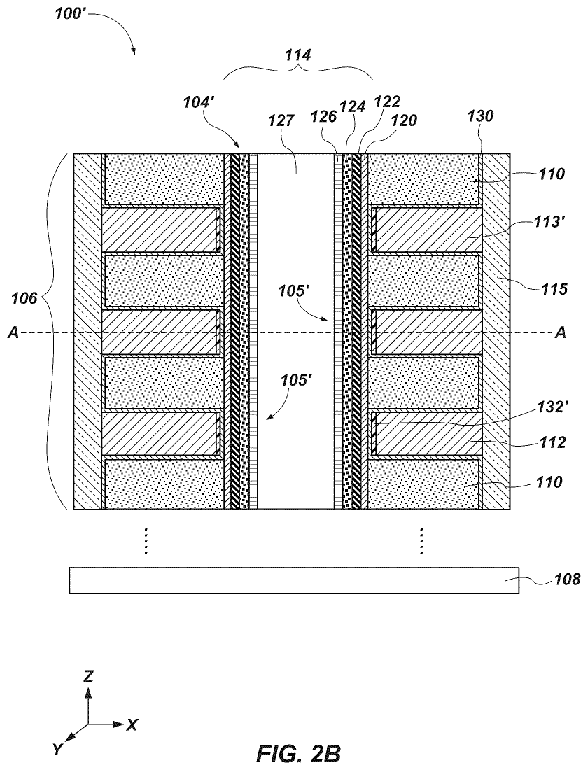

In additional embodiments, the method of forming a microelectronic device described herein with reference to may be modified, resulting in a configuration of the microelectronic device structure 100 that differs from that shown in and described with reference to FIG. 1E. For example, FIGS. 2A through 2B are simplified, vertical cross-sectional views of different processing stages of a method of forming a microelectronic device structure (e.g., a memory device structure) for a microelectronic device (e.g., a memory device, such as a 3D NAND Flash memory device), according to additional embodiments of the disclosure. FIG. 2A depicts a processing stage following the processing stage previously described herein with reference to FIG. 1C. Namely, the processing stage of the FIG. 2A may be considered a modification to the processing stage previously described with reference to FIG. 1D. that effectuates a different configuration of the interfacial liner material 132 previously described with reference to FIG. 1D, as described in further detail below.

To avoid repetition, not all features shown in FIGS. 2A and 2B are described in detail herein. Rather, unless described otherwise below, a feature in one or more of FIGS. 2A and 2B designated by a reference numeral that is a 100 increment of the reference numeral of a feature previously described with reference to one or more of FIGS. 1A through 1E will be understood to be substantially similar to and have substantially the same function as the previously described feature. To identify features in FIGS. 2A and 2B that are formed to have different configurations, at least in part, relative to corresponding features of the microelectronic device structure 100 previously described with reference to one or more of FIGS. 1A through 1E, prime (′) designations are provided for such features in FIGS. 2A and 2B. As a non-limiting example, since the processing described in further detail below results in a different geometric configuration of the interfacial liner material 132 previously described with reference to FIG. 1D. an interfacial liner material 132′ is depicted in FIGS. 2A and 2B. However, it will be understood that the material composition, functions, and advantages of the interfacial liner material 132′ shown in FIGS. 2A and 2B are substantially the same as those of the interfacial liner material 132 shown in and previously described with reference to FIGS. 1D and 1E.

Referring to FIG. 2A, the interfacial liner material 132′ of the microelectronic device structure 100′ may be formed to be limited to vertically extending surfaces of the high-K dielectric material 130 within the voids 113. As a result, horizontally extending surfaces of the high-K dielectric material 130 within the voids 113 and vertically extending surfaces of the high-K dielectric material 130 outside of the voids 113 may be free of the interfacial liner material 132′ prior to the additional processing described below with reference to FIG. 2B.

To form the interfacial liner material 132′, an initial interfacial liner material (e.g., having a geometric configuration corresponding to that of the interfacial liner material 132 (FIG. 1D)) may be continuously formed (e.g., conformally deposited) on surfaces (e.g., vertically extending surfaces, horizontally extending surfaces) of the high-K dielectric material 130 inside and outside of the voids 113, and then portions of the initial interfacial liner material on the horizontally extending surfaces of the high-K dielectric material 130 within the voids 113 and the vertically extending surfaces of the high-K dielectric material 130 outside of the voids 113 may be removed (e.g., recessed). The resulting interfacial liner material 132′ may extend over (e.g., horizontally extend over, vertically extend over) and substantially cover the vertically extending surfaces of the high-K dielectric material 130 within the voids 113.

Referring next to FIG. 2B. following the formation of the interfacial liner material 132′, remaining portions of the voids 113 (FIG. 2A) may be filled with the conductive fill material, and then portions of the conductive fill material outside of the boundaries of the voids 113 (FIG. 2A) may be removed (e.g., etched) to form discrete levels of the interfacial liner material 132′ and the conductive fill material 112. Thereafter, the resulting slots may be filled with dielectric material (e.g., SiOₓ) to form the dielectric slot structures 115. The discrete levels of the interfacial liner material 132′ and the conductive fill material 112 may form conductive structures 113′ of the microelectronic device structure 100′. In turn, intersections of the pillar structures 104 and some of the conductive structures 113′, together with portions of the high-K dielectric material 130 therebetween, may form vertically extending strings 104′ of memory cells 105′ for the microelectronic device structure 100′ (and, hence, a microelectronic device formed to include the microelectronic device structure 100′).

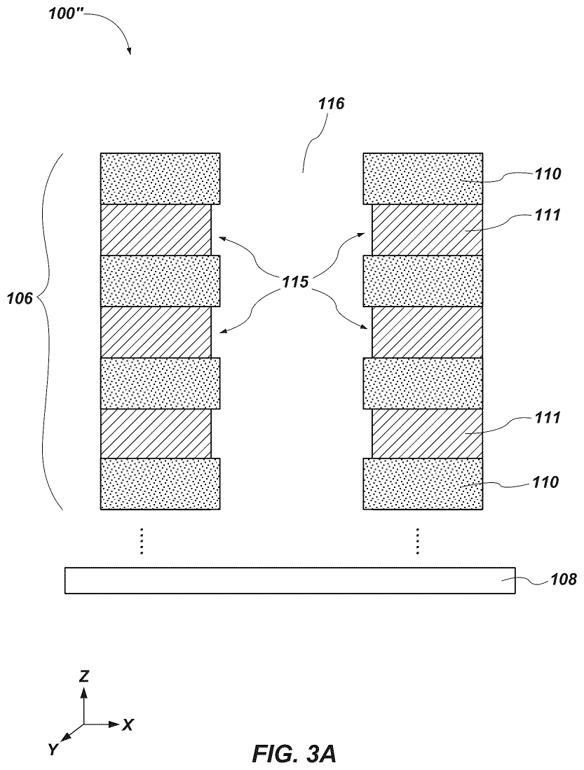

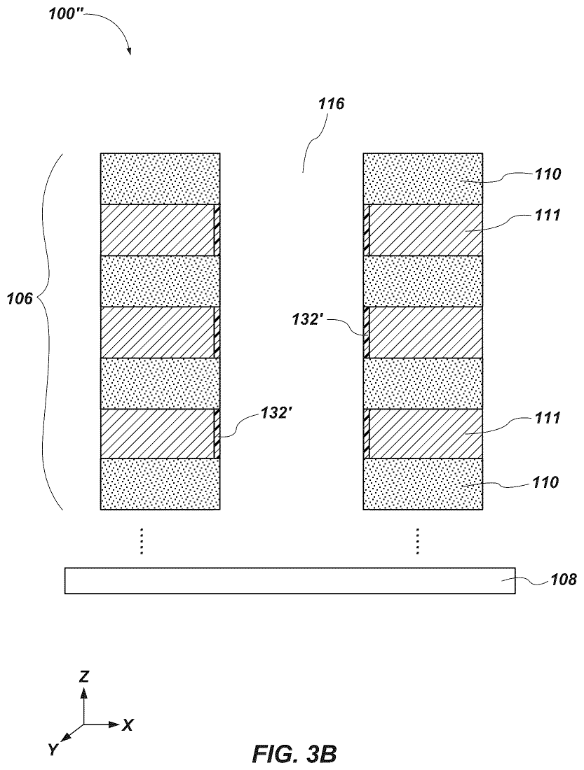

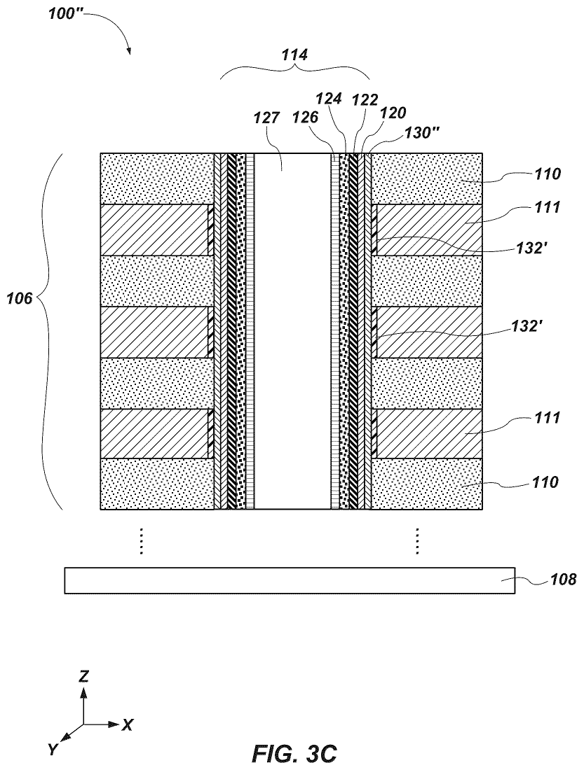

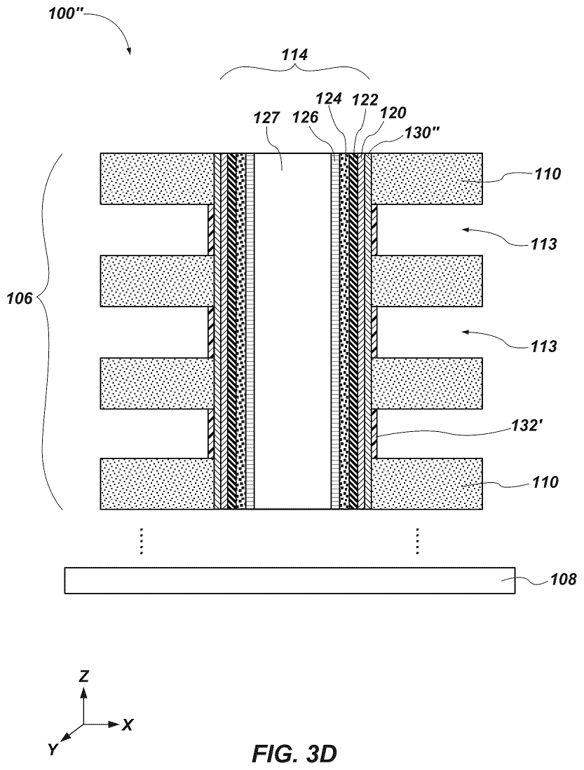

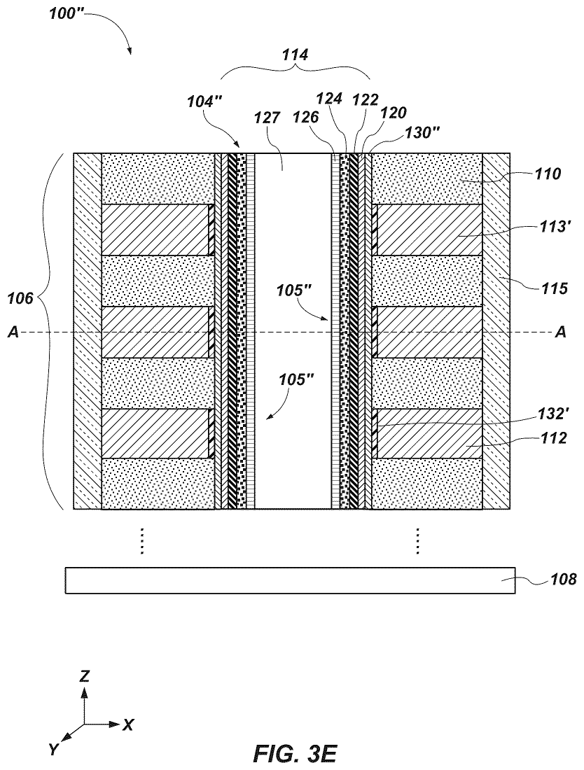

In further embodiments, a different process flow is employed to arrive at the configuration of the microelectronic device structure 100′ shown in and described with reference to FIG. 2B. For example, FIGS. 3A through 3E are simplified, vertical cross-sectional views of different processing stages of a method of forming a microelectronic device structure (e.g., a memory device structure) for a microelectronic device (e.g., a memory device, such as a 3D NAND Flash memory device), according to further embodiments of the disclosure.

To avoid repetition, not all features shown in FIGS. 3A through 3E are described in detail herein. Rather, unless described otherwise below, a feature in one or more of FIGS. 3A through 3E designated by a reference numeral that is a 100 increment of the reference numeral of a feature previously described with reference to one or more of FIGS. 1A through 1E and FIGS. 2A and 2B will be understood to be substantially similar to and have substantially the same function as the previously described feature. To identify features in FIGS. 3A through 3E that are formed to have different configurations, at least in part, relative to corresponding features of the microelectronic device structure 100 and the microelectronic device structure 100′ previously described with reference to one or more of FIGS. 1A through 1E and FIGS. 2A and 2B, double prime (″) designations are provided for such features in FIGS. 3A through 3E. In addition, features in FIGS. 3A through 3E having substantially the same geometric configurations as corresponding features in FIGS. 1A through 1E and/or FIGS. 2A and 2B have the same no prime or single prime (′) designation in FIGS. 3A through 3E.

Referring to FIG. 3A, a microelectronic device structure 100″ may be formed to include the stack structure 106 of vertically alternating levels of the insulative material 110 and the sacrificial material 111 over the substrate 108, and at least one opening 116 (e.g., pillar opening) may be formed to vertically extend through the stack structure 106. An individual opening 116 may be formed to have horizontal boundaries that non-linearly extend in the Z-direction. For example, portions of the opening 116 may horizontally project outward at levels of the sacrificial material 111 as compared to additional portions of the opening 116 at levels of the insulative material 110. Following the formation of initial openings, portions of the sacrificial material 111 of the levels of the sacrificial material 111 exposed by the initial openings may be selectively removed to form horizontal recesses 115 in the levels of the sacrificial material 111. Put another way, the sacrificial material 111 of the levels of the sacrificial material 111 may be selectively recessed back relative to the insulative material 110 of the levels of insulative material 110. An individual opening 116 may comprise a combination of an initial opening and the horizontal recesses 115 effectuated by and continuous with the initial opening.

Referring next to FIG. 3B, the recesses 115 (FIG. 3A) may be at least partially (e.g., substantially) filled with the interfacial liner material 132′. The interfacial liner material 132′ may be substantially confined to the recesses 115 (FIG. 3A). To form the interfacial liner material 132′, an initial interfacial liner material may be continuously formed (e.g., conformally deposited) on surfaces (e.g., vertically extending surfaces, horizontally extending surfaces) of at least the stack structure 106 defining the openings 116, and then portions of the initial interfacial liner material outside of the boundaries of the recesses 115 may be removed (e.g., recessed). The resulting interfacial liner material 132′ may extend over (e.g., horizontally extend over, vertically extend over) and substantially cover the vertically extending surfaces of the sacrificial material 111 of the levels of sacrificial material 111.

In next to FIG. 3C, high-K dielectric material 130″ and the pillar structures 114 (as previously described herein with reference to FIG. 1A) may be formed within the remaining portions of openings 116 (FIG. 3B). The high-K dielectric material 130″ may be formed (e.g., conformally formed) on surfaces of the levels of the insulative material 110 and the levels the interfacial liner material 132′ exposed by remaining portions of the openings 116 (FIG. 3B). Thereafter, the charge-blocking material 120 is formed (e.g., conformally formed) on or over the high-K dielectric material 130″ with the openings 116 (FIG. 3C). In additional embodiments, the high-K dielectric material 130″ is omitted (e.g., is not formed), and the charge-blocking material 120 is e.g., conformally formed on surfaces of the levels of the insulative material 110 and the levels the interfacial liner material 132′ exposed by remaining portions of the openings 116 (FIG. 3B). Following the formation of the charge-blocking material 120, the charge-trapping material 122, the tunnel dielectric material 124, the channel material 126, and the fill material 127 may be formed, in sequence, within still remaining portions of the openings 116 (FIG. 3C) to form the pillar structures 114 extending vertically through the stack structure 106.

Referring next to FIG. 3D, the microelectronic device structure 100″ of FIG. 3C is subjected to a material removal process (e.g., a stripping process, such as a wet nitride strip process) to selectively remove remaining portions of the levels of the sacrificial material 111 (FIG. 3C) relative to the levels of insulative material 110 and the levels of interfacial liner material 132′. As a non-limiting example, when the insulative material 110 includes SiO₂ and the sacrificial material 111 (FIG. 3C) includes Si₃N₄, the sacrificial material 111 may be selectively removed using phosphoric acid as an etchant. As shown in FIG. 3D, the removal of the remaining portions of the levels of sacrificial material 111 (FIG. 3C) may effectuate the formation of voids 113 vertically alternating with the levels of insulative material 110. The voids 113 may respective be at least partially defined by exposed surfaces of the insulative material 110 (e.g., of two levels of the insulative material 110) and the interfacial liner material 132.

Referring next to FIG. 3E, the voids 113 (FIG. 3D) may be filled with the conductive fill material 112, and then portions of the conductive fill material 112 outside of the boundaries of the voids 113 (FIG. 3D) may be removed (e.g., etched) to form discrete levels of the conductive fill material 112. Thereafter, the resulting slots may be filled with dielectric material (e.g., SiOₓ) to form the dielectric slot structures 115. The discrete levels of the interfacial liner material 132′ and the conductive fill material 112 may form the conductive structures 113′ of the microelectronic device structure 100″. As shown in FIG. 3E, aside from dimension changes imparted by the different configuration of the high-K dielectric material 130″, the conductive structures 113′ of the microelectronic device structure 100″ may be structurally similar to the conductive structures 113′ of the microelectronic device structure 100′ shown in FIG. 2B, as so the same single prime designation has been used in FIG. 1E. In turn, intersections of the pillar structures 104 and some of the conductive structures 113′, together with portions of the high-K dielectric material 130″ therebetween, may form vertically extending strings 104″ of memory cells 105″ for the microelectronic device structure 100″ (and, hence, a microelectronic device formed to include the microelectronic device structure 100″).

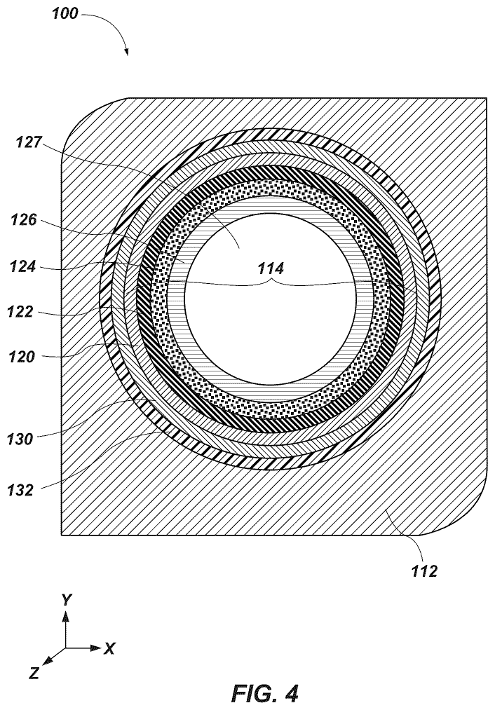

FIGS. 4 through 6 are simplified, horizontal cross-sectional views of a portion of the microelectronic device structure 100 at the processing stage of FIG. 1E, taken through a dashed line A-A depicted in FIG. 1E, in accordance with different embodiments of the disclosure. While described with reference to microelectronic device structure 100 (FIG. 1E), it will be understood that configurations shown in and described with reference to FIGS. 4 through 6 may also be used in the microelectronic device structure 100′ (FIG. 2B) and the microelectronic device structure 100″ (FIG. 3E) previously described herein. Accordingly, it will be understood that with appropriate accounting for the single prime (′) and double prime (″) designations of FIGS. 2B and 3E, FIGS. 4 through 6 may also be considered simplified, horizontal cross-sectional views of a portion of the microelectronic device structure 100′ (FIG. 2B) and the microelectronic device structure 100″ (FIG. 3E), taken through the dashed line A-A depicted in FIGS. 2B and 3E.

Referring first to FIG. 4, in some embodiments, the interfacial liner material 132 (and, hence, the interfacial liner material 132′ (FIG. 2B) and the interfacial liner material 132′ (FIG. 3E)) is formed to have a single layer (e.g., non-multilayer) structure. For example, the interfacial liner material 132 have a generally annular horizontal cross-sectional shape along the line A-A (FIG. 1E), and may only include a single Mo-containing material selected from molybdenum oxide, molybdenum nitride, and molybdenum oxynitride. The pillar structure 114 may be formed to include a fill material 127 laterally surrounded by the channel material 126. The channel material 126 is laterally surrounded by the charge-storage material 122, with the charge-tunneling material 124 positioned between the channel material 126 and the charge-storage material 122. The charge-storage material 122 is laterally surrounded by the charge-blocking material 120. In other words, one side of the lateral boundaries of the charge-storage material 122 is adjacent to the charge-tunneling material 124, and the other opposite side of the lateral boundaries of the charge-storage material 122 is adjacent to the charge-blocking material 120. The charge-blocking material 120 is laterally surrounded by the high K dielectric material 130, and the interfacial liner material 132 is positioned between the high-K dielectric material 130 and the conductive fill material 112. As shown in FIG. 4, the pillar structure 114 may have a circular horizontal cross-sectional shape along the line A-A (FIG. 1E). However, the disclosure is not limited, and the pillar structure 114 may have a different horizontal cross-sectional shape, such as an elliptical horizontal cross-sectional shape.

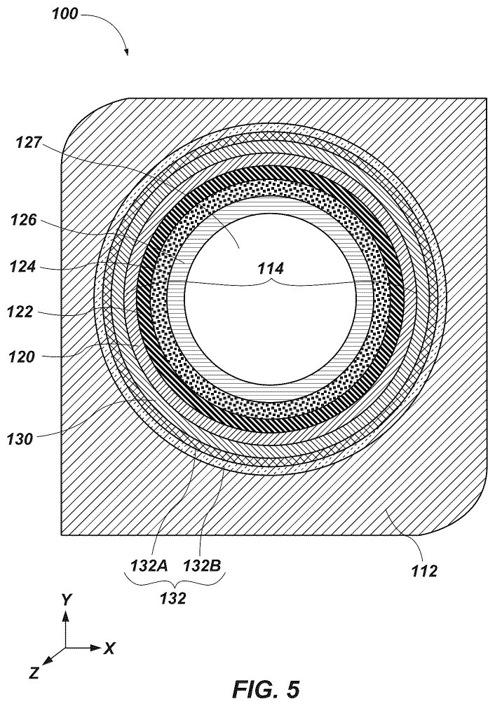

Referring next to FIG. 5, in additional embodiments, the interfacial liner material 132 (and, hence, the interfacial liner material 132′ (FIG. 2B) and the interfacial liner material 132′ (FIG. 3E)) is formed to have a multilayer structure. For example, the interfacial liner material 132 have a generally annular horizontal cross-sectional shape along the line A-A (FIG. 1E), but may include a first portion 132A having a first material composition, and a second portion 132B outwardly surrounding the first portion 132A having a second material composition different than the first material composition. For example, the first portion 132A of the interfacial liner material 132 may include a first Mo-containing material selected from molybdenum oxide, molybdenum nitride, and molybdenum oxynitride; and the second portion 132B of the interfacial liner material 132 may include a second, different Mo-containing material selected from molybdenum oxide, molybdenum nitride, and molybdenum oxynitride. The first portion 132A of the interfacial liner material 132 may be formed on the high-K dielectric material 130, and the second portion 132B of the interfacial liner material 132 may be formed on the first portion 132A of the interfacial liner material 132. In some embodiments, the first portion 132A of the interfacial liner material 132 and the second portion 132B of the interfacial liner material 132 each have a generally annular horizontal cross-sectional shape along the line A-A (FIG. 1E), and the second portion 132B of the interfacial liner material 132 concentrically surrounds the first portion 132A of the interfacial liner material 132. As shown in FIG. 5, the pillar structure 114 may have a circular horizontal cross-sectional shape along the line A-A (FIG. 1E). However, the disclosure is not limited, and the pillar structure 114 may have a different horizontal cross-sectional shape, such as an elliptical horizontal cross-sectional shape.

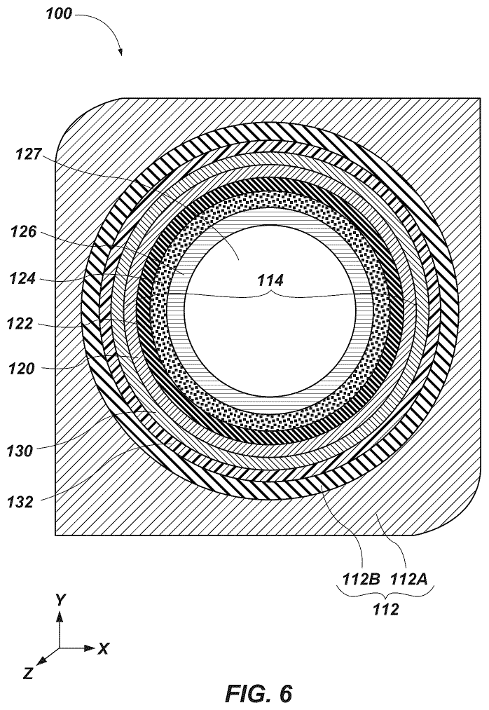

Referring next to FIG. 6, in further embodiments, the conductive fill material 112 is formed to have a multilayer structure. For example, the conductive fill material 112 may include a first portion 112A having a first material composition, and a second portion 112B interposed between the first portion 112A and the interfacial liner material 132 having a second material composition different than the first material composition. For example, the first portion 112A of the conductive fill material 112 may include a first conductive material (e.g., a conductive material substantially free Mo, such as elemental W and/or TiN); and the second portion 112B of the conductive fill material 112 may include a second, different conductive material (e.g., a Mo-containing conductive material, such as elemental Mo and/or an Mo alloy). The second portion 112B of the conductive fill material 112 may be formed on the interfacial liner material 132, and the first portion 112A of the conductive fill material 112 may be formed on the second portion 112B of the conductive fill material 112. As shown in FIG. 5. the pillar structure 114 may have a circular horizontal cross-sectional shape along the line A-A (FIG. 1E). However, the disclosure is not limited, and the pillar structure 114 may have a different horizontal cross-sectional shape, such as an elliptical horizontal cross-sectional shape. Thus, in accordance with embodiments of the disclosure, a microelectronic device includes a stack structure, a pillar structure, and an interfacial liner material. The stack structure includes levels of conductive material vertically alternating with levels of insulative material. The pillar structure includes semiconductor material vertically extending through the stack structure. The interfacial liner material is horizontally interposed between the pillar structure and the levels of the conductive material of the stack structure. The interfacial liner material has a work function within a range of from about 4.6 eV to about 6.0 eV.

Furthermore, in accordance with embodiments of the disclosure, a method of forming a microelectronic device includes forming a stack structure including levels of sacrificial material vertically alternating with levels of insulative material. A pillar structure is formed to vertically extend through the stack structure. The pillar structure includes semiconductor material. Portions of the sacrificial material of the levels of sacrificial material are replaced with an interfacial liner material having a work function within a range of from about 4.6 eV to about 6.0 eV. Additional portions of the sacrificial material of the levels of sacrificial material are replaced with conductive material having a different work function than the insulative liner material. The interfacial liner material is horizontally interposed between the pillar structure and the conductive material.

Moreover, in accordance with embodiments of the disclosure, a memory device includes a stack structure and strings of memory cells vertically extending through the stack structure. The stack structure includes conductive structures vertically alternating with insulative structures. The conductive structures respectively include an interfacial liner material and conductive material neighboring the interfacial liner material. The interfacial liner material includes one or more of molybdenum oxide, molybdenum nitride, and molybdenum oxynitride. The conductive material has a different material composition than the interfacial liner material. The interfacial liner of respective ones of the conductive structures of the stack structure is horizontally interposed between channel material of the strings of memory cells and the conductive material of the respective ones of the conductive structures of the stack structure.

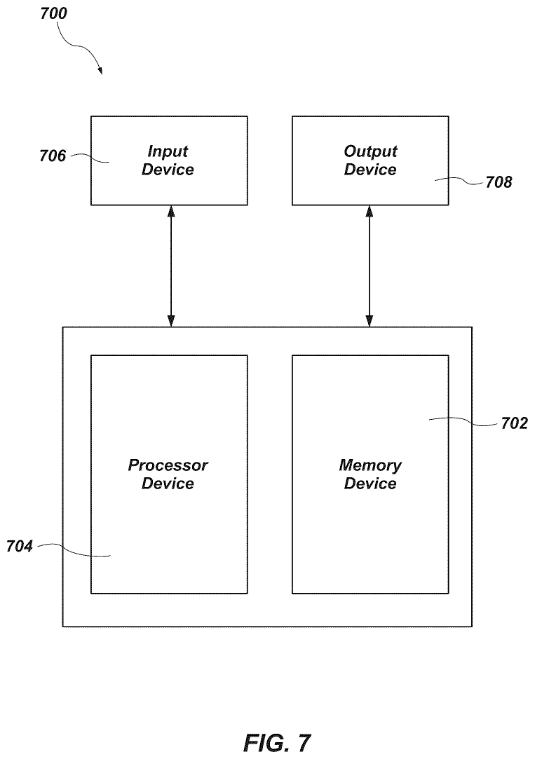

Microelectronic devices structures (e.g., one of the microelectronic structures 100, 100′, 100″ of FIGS. 1E, 2B, and 3E) in accordance with embodiments of the disclosure may be used in embodiments of electronic systems of the disclosure. For example, FIG. 7 is a block diagram of an electronic system 700 according to embodiments of disclosure. The electronic system 700 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 700 includes at least one memory device 702. The memory device 702 may comprise, for example, one or more of a microelectronic device structure (e.g., one of the microelectronic structures 100, 100′, 100″ of FIGS. 1E, 2B, and 3E). The electronic system 700 may further include at least one electronic signal processor device 704 (often referred to as a “microprocessor”). The electronic signal processor device 704 may, optionally, include one or more of a microelectronic device structure (e.g., one of the microelectronic structures 100, 100′, 100″ of FIGS. 1E, 2B, and 3E). While the memory device 702 and the electronic signal processor device 704 are depicted as two (2) separate devices in FIG. 7, in additional embodiments, a single (e.g., only one) memory/processor device having the functionalities of the memory device 702 and the electronic signal processor device 704 may be included in the electronic system 700. In such embodiments, the memory/processor device may include one or more of a microelectronic device structure (e.g., one of the microelectronic structures 100, 100′, 100″ of FIGS. 1E, 2B, and 3E). The electronic system 700 may further include one or more input devices 706 for inputting information into the electronic system 700 by a user, such as, for example, a mouse or other pointing device, a keyboard, a touchpad, a button, or a control panel. The electronic system 700 may further include one or more output devices 708 for outputting information (e.g., visual or audio output) to a user such as, for example, a monitor, a display, a printer, an audio output jack, a speaker, etc. In some embodiments, the input device 706 and the output device 708 comprise a single touchscreen device that can be used both to input information to the electronic system 700 and to output visual information to a user. The input device 706 and the output device 708 may communicate electrically with one or more of the memory device and the electronic signal processor device 704.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a stack structure including levels of conductive material vertically alternating with levels of insulative material;
a pillar structure comprising semiconductor material vertically extending through the stack structure; and
an interfacial liner material horizontally interposed between the pillar structure and the levels of the conductive material of the stack structure, the interfacial liner material having a work function within a range of from about 4.6 electronvolts (eV) to about 6.0 eV.

2. The microelectronic device of claim 1, wherein the interfacial liner material comprises one or more of molybdenum oxide, molybdenum nitride, and molybdenum oxynitride.

3. The microelectronic device of claim 2, wherein the interfacial liner material comprises two or more of the molybdenum oxide, the molybdenum nitride, and the molybdenum oxynitride.

4. The microelectronic device of claim 1, wherein the conductive material of the levels of conductive material has an additional work function within a range of from about 3.5 eV to about 4.6 eV.

5. The microelectronic device of claim 4, wherein the conductive material comprises molybdenum.

6. The microelectronic device of claim 1, wherein the interfacial liner material substantial covers first vertically extending surfaces of the conductive material of the levels of conductive material horizontally neighboring the pillar structure.

7. The microelectronic device of claim 6, wherein the interfacial liner material further substantial covers horizontally extending surfaces of the conductive material of the levels of conductive material.

8. The microelectronic device of claim 1, wherein the interfacial liner material has a higher work function than the conductive material of the levels of conductive material.

9. The microelectronic device of claim 1, further comprising a high-K dielectric material horizontally extending from and between charge-blocking material of the pillar structure and the interfacial liner material.

10. A method of forming a microelectronic device, comprising:
forming a stack structure comprising levels of sacrificial material vertically alternating with levels of insulative material;
forming a pillar structure to vertically extend through the stack structure, the pillar structure comprising semiconductor material;
replacing portions of the sacrificial material of the levels of sacrificial material with an interfacial liner material having a work function within a range of from about 4.6 electronvolts (eV) to about 6.0 eV; and
replacing additional portions of the sacrificial material of the levels of sacrificial material with a conductive material having a different work function than the interfacial liner material, the interfacial liner material horizontally interposed between the pillar structure and the conductive material.

11. The method of claim 10, further comprising selecting the interfacial liner material to comprise one or more of molybdenum oxide, molybdenum nitride, and molybdenum oxynitride.

12. The method of claim 10, wherein replacing the additional portions of the sacrificial material of the levels of sacrificial material with the conductive material having a different work function than the interfacial liner material comprises:
replacing the additional portions of the sacrificial material of the levels of sacrificial material with a conductive material such that the work function is decreasing laterally from the interfacial liner material to the conductive material.

13. The method of claim 10, further comprising forming the interfacial liner material to comprise:
a first molybdenum-containing material horizontally surrounding the pillar structure and having a first material composition; and
a second molybdenum-containing material horizontally surrounding the first molybdenum-containing material and having a second material composition different than the first material composition.

14. The method of claim 10, further comprising forming a high-K dielectric material horizontally between the pillar structure and the interfacial liner material.

15. The method of claim 10, further comprising forming the pillar structure before replacing the portions of the sacrificial material of the levels of sacrificial material with the interfacial liner material.

16. The method of claim 10, further comprising forming the pillar structure after replacing the portions of the sacrificial material of the levels of sacrificial material with the interfacial liner material.

17. A memory device, comprising:
a stack structure including conductive structures vertically alternating with insulative structures, the conductive structures respectively comprising:
an interfacial liner material comprising one or more of molybdenum oxide, molybdenum nitride, and molybdenum oxynitride; and
conductive material neighboring the interfacial liner material and having a different material composition than the interfacial liner material; and
strings of memory cells vertically extending through the stack structure, the interfacial liner of respective ones of the conductive structures of the stack structure horizontally interposed between channel material of the strings of memory cells and the conductive material of the respective ones of the conductive structures of the stack structure.

18. The memory device of claim 17, wherein:
the interfacial liner material of the respective ones of the constructive structures has a first work function within a range of from about 4.6 eV to about 6.0 eV; and
the conductive material of the respective ones of the constructive structures has a second work function within a range of from about 3.5 eV to about 4.6 eV.

19. The memory device of claim 17, wherein, for the respective ones of the conductive structures, the interfacial liner material thereof substantially continuously covers a vertically extending surface and horizontally extending surfaces of the conductive material thereof.

20. The memory device of claim 17, wherein, for the respective ones of the conductive structures:
a vertically extending surface of the conductive material thereof is substantially covered by the interfacial liner material thereof; and
horizontally extending surfaces of the conductive material thereof are substantially free of the interfacial liner material thereof.
